(19) United States
(12) Patent Application Publication
(10) Pub. No.: US 2012/0181683 A1
(43) Pub. Date: Jul. 19, 2012

(54) THREE-DIMENSIONALLY INTEGRATED SEMICONDUCTOR DEVICE AND ELECTRONIC DEVICE INCORPORATION BY REFERENCE

(76) Inventors: TAKAO YAMAZAKI, Tokyo (JP); Shizuaki Masuda, Shizuoka (JP)

(21) Appl. No.: 13/351,409

(22) Filed: Jan. 17, 2012

(30) Foreign Application Priority Data
Jan. 17, 2011 (JP) 6890/2011

(51) Int. Cl. H01L 27/06

(52) U.S. Cl. 257/704; 257/E27.027

(57) ABSTRACT

A three-dimensionally integrated semiconductor device includes a flexible circuit substrate which has a lower portion, an upper portion, and at least one side portion, a support body which supports the upper portion of the flexible circuit substrate, and at least two devices mounted on the flexible circuit substrate and wherein at least one of the devices is mounted on an upper surface of the lower portion of the flexible circuit substrate, at least one of the other devices is mounted on a lower surface of the upper portion of the flexible circuit substrate, and a gap is provided between the device mounted on the upper surface of the lower portion of the flexible circuit substrate and the device mounted on the lower surface of the upper portion of the flexible circuit substrate.

### INCORPORATION BY REFERENCE

This application is based upon and claims the benefit of priority from Japanese Patent Application No. JP 2011-006890, filed on Jan. 17, 2011, the disclosure of which is incorporated herein in its entirety by reference.

### BACKGROUND OF THE INVENTION

1. Technical Field

The present invention relates to a three-dimensionally integrated semiconductor device and an electronic device mounting the same.

2. Background Art

In recent years, many technologies of three-dimensionally integrate semiconductor devices are proposed as a technology to reduce a mounting area for a plurality of semiconductor devices. For example, a typical example of a three-dimensional integration technology is disclosed in patent document 1 (U.S. Pat. No. 6,225,688) (refer to FIG. 1).

As shown in FIG. 1, in a three-dimensionally integrated semiconductor device described in patent document 1, a flexible circuit substrate 102 is bent. By this, (1) a plurality of semiconductor devices 101 are mounted on the same one surface of the flexible circuit substrate 102. Additionally, (2) a plurality of semiconductor devices 101 are stacked in a vertical direction. Further, two semiconductor devices 101 are bonded by an adhesive agent 103. Further, the flexible circuit substrate 102 is mounted on a rigid element 104. Further, the assembly is secured within the bracket 105. Furthermore, a conductive terminal 106 that is an external terminal is provided at the lowermost position.

Thus, the three-dimensionally integrated semiconductor device described in patent document 1 has merit in which the mounting area for the plurality of semiconductor devices can be reduced in comparison with a case in which the plurality of semiconductor devices 101 are simply mounted on the same plane surface of a printed circuit board. For this reason, the three-dimensionally integrated semiconductor device described in patent document 1 can be suitably mounted in a small electronic device such as a mobile device.

Additionally, in the three-dimensionally integrated semiconductor device described in patent document 1, when the plurality of semiconductor devices 101 are mounted on the flexible circuit substrate 102 through a reflow process, one time of the reflow process is enough. Therefore, the three-dimensionally integrated semiconductor device described in patent document 1 has merit in which performance degradation of the semiconductor device 101 due to heat history in the reflow process can be prevented.

### SUMMARY

Although the semiconductor device of the present invention is a small three-dimensionally integrated semiconductor device in which a plurality of semiconductor devices are integrated, even when a device with large power consumption (a device that generates a large amount of heat) is used as a semiconductor device in it, the heat generated by the device is less conducted to another semiconductor device and whereby, malfunction of the semiconductor device does not occur. Therefore, an object of the present invention is to provide a high-performance semiconductor device.

When such semiconductor device or the three-dimensionally integrated semiconductor device is mounted in a module and an electronic device, the thickness of the module and the electronic device can be reduced and the mounting area can be reduced. Therefore, an object of the present invention is to provide a module and an electronic device that are lightweight and low in price.

A three-dimensionally integrated semiconductor device includes a flexible circuit substrate which has a lower portion, an upper portion, and at least one side portion, a support body which supports the upper portion of the flexible circuit substrate, and at least two devices mounted on the flexible circuit substrate and wherein at least one of the devices is mounted on an upper surface of the lower portion of the flexible circuit substrate, at least one of the other devices is mounted on a lower surface of the upper portion of the flexible circuit substrate, and a gap is provided between the device mounted on the upper surface of the lower portion of the flexible circuit substrate and the device mounted on the lower surface of the upper portion of the flexible circuit substrate.

### BRIEF DESCRIPTION OF THE DRAWINGS

Exemplary features and advantages of the present invention will become apparent from the following detailed description when taken with the accompanying drawings in which:

FIG. 1 is a cross-sectional view of a three-dimensionally integrated semiconductor device according to a related art;

FIG. 2 is a cross-sectional view of a semiconductor device according to a first exemplary embodiment of the present invention;

FIG. 3 is a figure (top view) of an assembly in which a device 1 and a device 2 are mounted on a first surface of a flexible circuit substrate used for a semiconductor device of the present invention in a plane arrangement;

FIG. 4 is a figure (top view) of an assembly in which after mounting a device 1 and a device 2 on the flexible circuit substrate, a support body in which a penetration hole is provided so as to surround the device 1 is bonded on a first surface of the flexible circuit substrate or is connected to an external electrode formed on the first surface;

FIG. 5 is a cross-sectional view showing a cross section along line 5-5′ in FIG. 4;

FIG. 6 is a cross-sectional view of an assembly in which a semiconductor device of a first exemplary embodiment of the present invention is mounted on a mounting board;

FIG. 7 is a figure showing a flow path of heat when a semiconductor device of a first exemplary embodiment of the present invention that is mounted on a mounting board is operated;

FIG. 8 is a cross-sectional view of a semiconductor device of a second exemplary embodiment of the present invention;

FIG. 9 is a cross-sectional view of a modified example (first example) of a semiconductor device of a second exemplary embodiment of the present invention;

FIG. 10 is a cross-sectional view of a modified example (second example) of a semiconductor device of a second exemplary embodiment of the present invention;

FIG. 11 is a cross-sectional view of a semiconductor device of a third exemplary embodiment of the present invention;

FIG. 12 is a figure (top view) of an assembly in which a device 1 and a device 2 are mounted on a first surface of a flexible circuit substrate used for a semiconductor device of the present invention in a plane arrangement;

FIG. 13 is a cross-sectional view showing a cross section along line 13-13′ in FIG. 12;

FIG. 14 is a cross-sectional view of a semiconductor device of a fourth exemplary embodiment of the present invention;

FIG. 15 is a figure (top view) of an assembly in which a device 1 and a device 2 are mounted on a first surface of a flexible circuit substrate used for a semiconductor device of the present invention in a plane arrangement;

FIG. 16 is a cross-sectional view showing a cross section along line 16-16′ in FIG. 15;

FIG. 17 is a cross-sectional view of a semiconductor device of a fifth exemplary embodiment of the present invention;

FIG. 18 is a figure (top view) of an assembly in which a device 1 and a device 2 are mounted on a first surface of a flexible circuit substrate used for a semiconductor device of the present invention in a plane arrangement;

FIG. 19 is a cross-sectional view showing a cross section along line 19-19′ in FIG. 18;

FIG. 20 is a cross-sectional view of a semiconductor device of a sixth exemplary embodiment of the present invention;

FIG. 21 is a cross-sectional view of a semiconductor device of a seventh exemplary embodiment of the present invention;

FIG. 22 is a cross-sectional view of a semiconductor device of an eighth exemplary embodiment of the present invention;

FIG. 23 is a figure (top view) of an assembly in which a device 1, a device 2, and passive components (capacitor, resistor, inductor, and the like) are mounted on a first surface of a flexible circuit substrate used for a semiconductor device of the present invention in a plane arrangement;

FIG. 24 is a figure (top view) of an assembly in which after mounting a device 1, a device 2, and passive components on a flexible circuit substrate, a support body in which a penetration hole is provided so as to surround a device A and the passive components is bonded to a first surface of the flexible circuit substrate or is connected to an external electrode formed on the first surface;

FIG. 25 is a cross-sectional view showing a cross section along line 25-25′ in FIG. 24;

FIG. 26 is a cross-sectional view of a semiconductor device of a ninth exemplary embodiment of the present invention;

FIG. 27 is a figure (top view) of an assembly in which a device 1, a device 2, passive components, and a support body are mounted on a first surface of a flexible circuit substrate used for a semiconductor device of the present invention in a plane arrangement;

FIG. 28 is a cross-sectional view showing a cross section along line 28-28′ in FIG. 27;

FIG. 29 is a cross-sectional view of a semiconductor device 1;

FIG. 30 is a cross-sectional view of a semiconductor device 2;

FIG. 31 is an outside view (top view) of a support body in which a penetration hole is provided in a center thereof;

FIG. 32 is a cross-sectional view showing an example of a flexible circuit substrate; and

FIG. 33 is a cross-sectional view of a three-dimensionally integrated semiconductor device (a state before mounting an external terminal) described in an example.

### EXEMPLARY EMBODIMENT

Exemplary embodiments of the present invention will now be described in detail in accordance with the accompanying drawings.

Hereinafter, a mode for carrying out the present invention will be described in detail with reference to the drawing.

### First Exemplary Embodiment

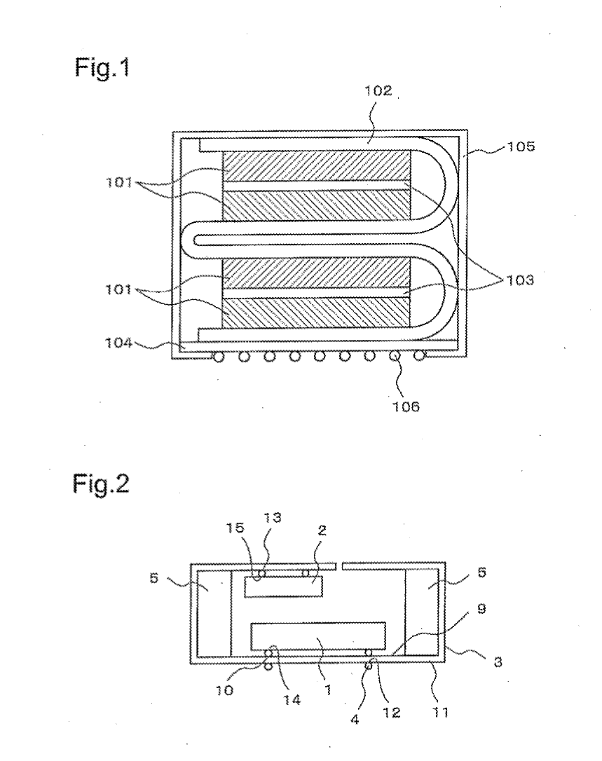

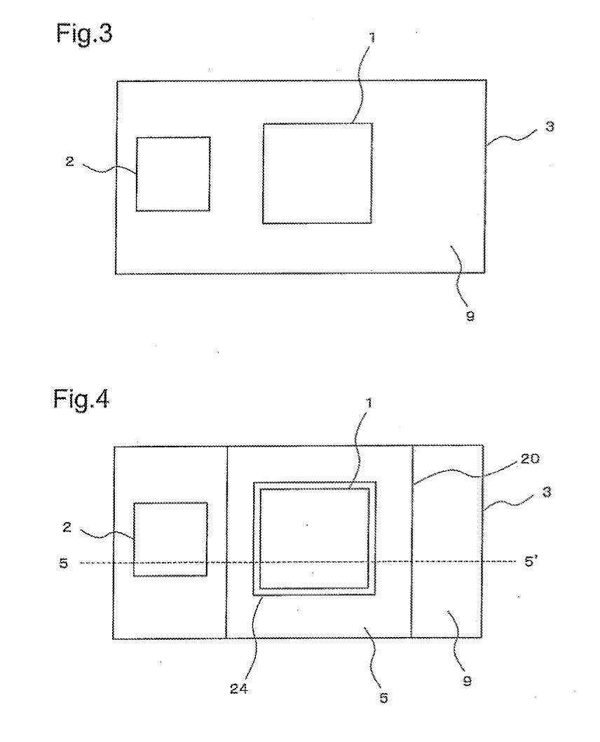

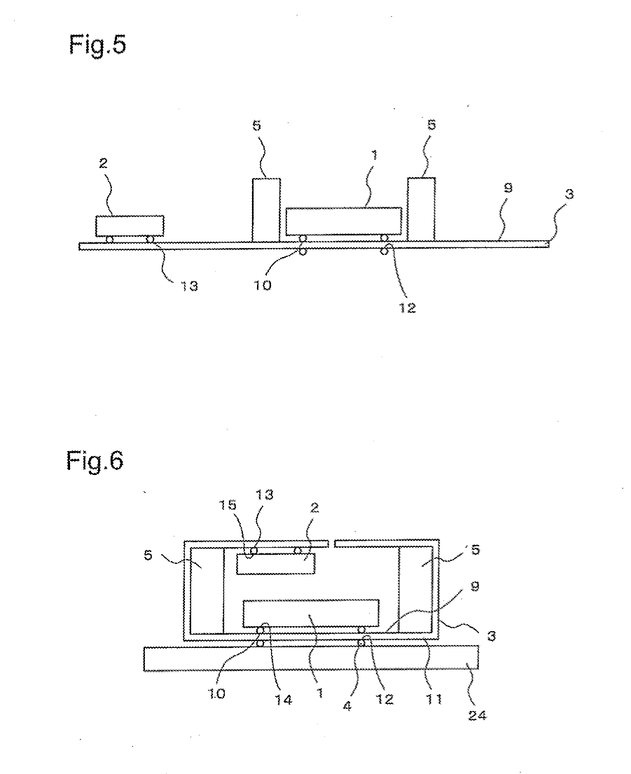

FIG. 2 is a cross-sectional view of a semiconductor device showing a first exemplary embodiment of the present invention. FIG. 3 is a figure (top view) of an assembly in which a device 1 and a device 2 are mounted on a first surface 9 of a flexible circuit substrate 3 used for a semiconductor device of the present invention in a plane arrangement. FIG. 4 is a figure (top view) of an assembly in which after mounting the device 1 and the device 2 on the flexible circuit substrate 3, a support body 5 in which a penetration hole 24 is provided so as to surround the device 1 is bonded to the first surface 9 of the flexible circuit substrate 3 or is connected to an external electrode 10 formed on the first surface 9. FIG. 5 is a cross-sectional view showing a cross section along line 5-5′ in FIG. 4.

As shown in FIG. 2, in the semiconductor device of the first exemplary embodiment of the present invention, one flexible circuit substrate 3 having one or more wiring layers is used. One or more first external electrodes 10 and one or more second external electrodes 13 are provided on the first surface 9 of the flexible circuit substrate 3. One or more third external electrodes 12 are provided on a second surface 11 of the flexible circuit substrate 3. As shown in FIG. 2, the semiconductor device of the first exemplary embodiment of the present invention includes the device 1, the device 2, the support body 5, and an external terminal 4. The device 1 and the device 2 are positioned at a lower side and an upper side, respectively. One or more penetration holes 24 are provided in the support body 5 and the device 1 and the device 2 can be accommodated in the penetration hole 24. The external terminal 4 is electrically connected to an external electrode 12.

In FIG. 2, the device 1 is mounted on a part of a lower portion (lower side in FIG. 2) of the flexible circuit substrate 3. Namely, specifically, the device 1 is mounted on a part of an inner surface of the lower portion of the flexible circuit substrate 3 that is formed in a roll shape. The device 2 is mounted on a part of an upper portion (upper side in FIG. 2) of the flexible circuit substrate 3. Namely, specifically, the device 2 is mounted on a part of the inner surface of the upper portion of the flexible circuit substrate 3 that is formed in a roll shape. A side portion (right side and left side in FIG. 2) of the flexible circuit substrate 3 is a portion between the lower portion of the flexible circuit substrate 3 and the upper portion of the flexible circuit substrate 3. In FIG. 2, a cross section of the lower portion of the flexible circuit substrate 3 is a cross section of the lower side extending horizontally. A cross section of the upper portion of the flexible circuit substrate 3 is a cross section of an upper side extending horizontally. Cross sections of the side portions of the flexible circuit substrate 3 are cross sections of a right side and a left side that extend vertically.

The semiconductor device of the first exemplary embodiment of the present invention has a structure in which the end portions of the flexible circuit substrate 3 are bent along two sides of the support bodies 5 that face each other so that the device 1, the device 2, and the support body 5 are included therein. Further, the semiconductor device of the first exemplary embodiment of the present invention has a structure in which there is a gap between the device 1 and the device 2. Thus, the semiconductor device of the first exemplary embodiment has a structure in which heat generated by one of the devices does not conduct to the other device directly because there is the gap between the device 1 and the device 2. For example, in a case in which the device 1 is a CPU (Central Processing Unit) and the device 2 is a memory such as a DRAM, a flash memory, or the like, the CPU generally consumes a large amount of power and generates a large amount of heat. However, if the structure of the exemplary embodiment 1 of the present invention is used, the heat generated by the CPU is less conducted to the memory. In other words, the structure of the first exemplary embodiment of the present invention has an effect in which temperature rise of the device 2 can be suppressed because the heat generated by the device 1 is not conducted to the device 2 directly.

In the above-mentioned description, it is assumed that the temperature of the device 1 is the highest among the devices. However, even when the temperature of the device 2 is the highest among the devices, the heat generated by the device 2 is not conducted to the device 1 directly. For this reason, the semiconductor device of the first exemplary embodiment of the present invention has an effect in which temperature rise of the device 1 can be suppressed.

FIG. 6 is a cross-sectional view of an assembly in which the semiconductor device of the first exemplary embodiment of the present invention is mounted on a mounting board 24.

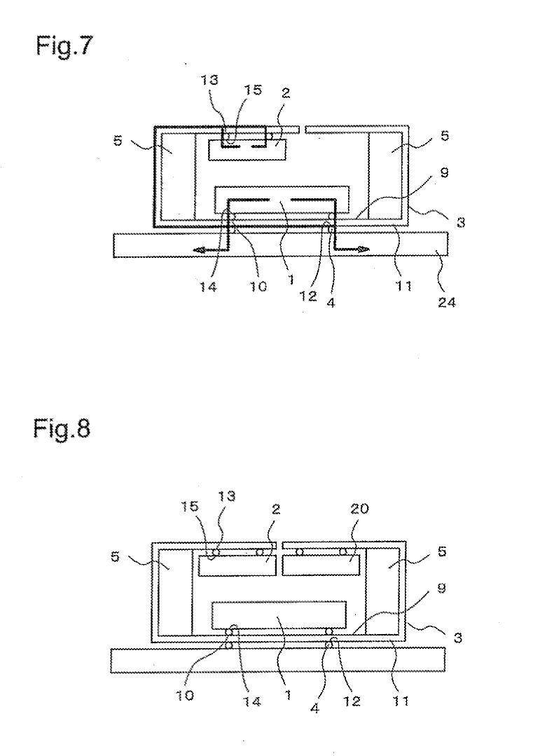

FIG. 7 is a figure showing a flow path of heat when the semiconductor device of the first exemplary embodiment of the present invention that is mounted on the mounting board 24 is operated.

As shown in FIG. 7, the heat generated by the device 1 is conducted to an external terminal 14 of the device 1 and then, it is conducted to the external electrode 10 of the flexible circuit substrate 3. After that, the heat generated by the device 1 is conducted to the external electrode 12 by a wiring in the flexible circuit substrate 3. After that, the heat generated by the device 1 is conducted to the external terminal 4 connected to the external electrode 12 and the heat is dissipated to the mounting board 24. The heat generated by the device 2 is conducted to an external terminal 15 of the device 2 and after that, it is conducted to the external electrode 13 of the flexible circuit substrate 3. After that, the heat generated by the device 2 is conducted to the external electrode 12 by the wiring in the flexible circuit substrate 3. After that, the heat generated by the device 2 is conducted to the external terminal 4 connected to the external electrode 12 and the heat is dissipated to the mounting board 24.

Here, for example, when the device 1 is in contact with the device 2 and the temperature of the device 1 is higher than that of the device 2, the heat generated by the device 1 is conducted to the device 2 and whereby, the temperature of the device 2 increases. However, in the structure of the first exemplary embodiment of the present invention, there is the gap between the device 1 and the device 2 and the device 1 is not contact with the device 2 through a member other than the flexible circuit substrate 3 and the support body 5. For this reason, in the semiconductor device of the first exemplary embodiment of the present invention, the heat generated by the device 1 is less conducted to the device 2 and temperature rise of the device 2 can be suppressed.

The external terminal 4 for the connection to the mounting board 24 is formed to the second external electrode 12 that exists on the second surface 11 of the flexible circuit substrate 3. For example, a so-called solder ball or the like composed of a metal material including Sn is preferably used as the external terminal 4. Here, the solder ball is used for the external terminal 4. However, needless to say, if a component has a shape for surface mounting, it can be used for the external terminal 4.

The device 1 and the device 2 are not limited in particular. A bare chip can be used for the device 1 and the device 2. However, a packaged semiconductor device that had been inspected (operation is guaranteed) may be used. When the packaged semiconductor device is used, an inspection cost (an investment cost for inspection equipment, a cost for inspection software development, or the like) can be substantially reduced in comparison with a case in which the semiconductor device of the exemplary embodiment is produced by using the semiconductor bare chip. Therefore, the use of the packaged semiconductor device has a merit of reducing a manufacturing cost.

A material of the support body 5 is not limited in particular. For example, a metal (iron, aluminum, an alloy including aluminum, an alloy including Ni and Fe, an alloy including Ni and Cr, an alloy including Cr, or copper), silicon, a resin material (nylon, polypropylene, epoxy resin, carbon, or aramid resin), mica or the like can be used for the material of the support body 5. Aluminum is preferred as the material of the support body 5 when a lightweight semiconductor device is desired. When the weight of the support body 5 is reduced by using another method, a method (not shown in the drawing) in which a penetration hole or a slot is provided in the support body 5 in order to reduce a volume of the material of which the support body 5 is composed is preferably used. Further, in order to extend a temperature cycle life of the semiconductor device, a material whose thermal expansion coefficient is approximately equal to that of the used semiconductor device is preferably used for the support body. For example, when a semiconductor bare chip is used for the semiconductor device and the bare chip is fabricated on a Si substrate, an alloy 42 material whose thermal expansion coefficient is approximately equal to that of Si is preferably used as the material of the support body 5.

### Second Exemplary Embodiment

FIG. 8 is a cross-sectional view of a semiconductor device showing a second exemplary embodiment of the present invention.

As shown in FIG. 8, in the semiconductor device of the second exemplary embodiment of the present invention, one flexible circuit substrate 3 having one or more wiring layers is used. One or more first external electrodes 10 and one or more second external electrodes 13 are provided on the first surface 9 of the flexible circuit substrate 3. One or more third external electrodes 12 are provided on the second surface 11 of the flexible circuit substrate 3. The semiconductor device of the second exemplary embodiment of the present invention includes the device 1, the device 2, a device 20, the support body 5, and the external terminal 4. The device 1 is positioned at a lower side and the devices 2 and 20 are positioned at an upper side. One or more penetration holes are provided in the support body 5 and the device 1, the device 2, and the device 20 are accommodated in the penetration hole. The external terminal 4 is electrically connected to the external electrode 12. In the second exemplary embodiment, in addition to the device 2, the device 20 is mounted above the device 1 (upper side in. FIG. 8). This is a difference between the first exemplary embodiment and the second exemplary embodiment.

The semiconductor device of the second exemplary embodiment of the present invention has a structure in which the end portions of the flexible circuit substrate 3 are bent along two sides of the support bodies 5 that face each other so that the device 1, the device 2, the device 20, and the support body 5 are included therein. Further, the semiconductor device of the second exemplary embodiment of the present invention has a structure in which there are gaps between the device 1 and the device 2, between the device 1 and the device 20, and between the device 2 and the device 20. Thus, because there are gaps between the device 1 and the device 2, between the device 1 and the device 20, and between the device 2 and the device 20, heat generated by the device 1 is not conducted to the device 2 and the device 20 directly. For this reason, the semiconductor device of the second exemplary embodiment of the present invention has an effect in which temperature rise of the device 2 and the device 20 can be suppressed.

In the above-mentioned description, it is assumed that the temperature of the device 1 is the highest among the devices. Further, even when the temperature of the device 2 is the highest among the devices, the heat generated by the device 2 is not conducted to the device 1 and the device 20 directly. Furthermore, even when the temperature of the device 20 is the highest among the devices, the heat generated by the device 20 is not conducted to the device 1 and the device 2 directly. For this reason, the semiconductor device of the second exemplary embodiment of the present invention has an effect in which temperature rise of the device with relatively small power consumption can be suppressed.

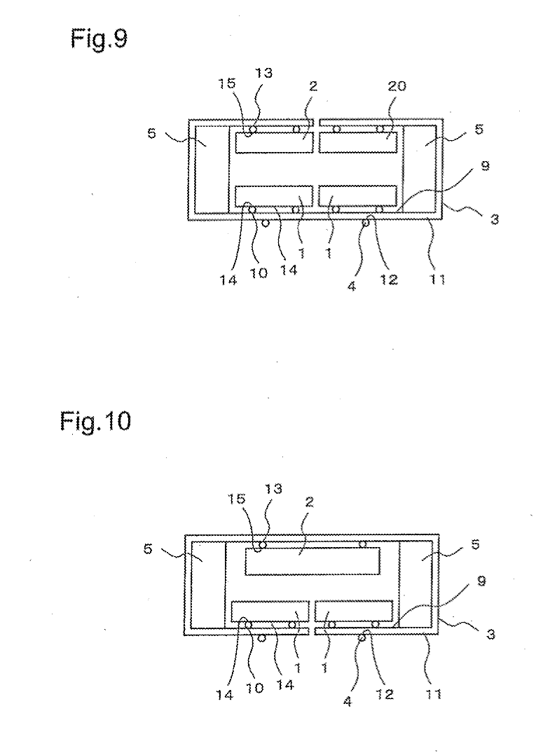

FIG. 9 is a cross-sectional view of a modified example (first example) of the semiconductor device of the second exemplary embodiment of the present invention.

In FIG. 8, three devices are used but in FIG. 9, four devices are used. This is a difference between them. Another device is mounted adjacent to the device 1. FIG. 9 shows an example of the semiconductor device in which four devices is used. In the same manner, this exemplary embodiment can be extended to a case in which five or more devices are mounted in the semiconductor device.

FIG. 10 is a cross-sectional view of a modified example (second example) of the semiconductor device showing the second exemplary embodiment of the present invention. In FIG. 10, the entire assembly of the flexible circuit substrate 3 on which all the devices are mounted is turned upside down in comparison with the entire assembly of the flexible circuit substrate 3 shown in FIG. 8, except for the second external electrode 12.

### Third Exemplary Embodiment

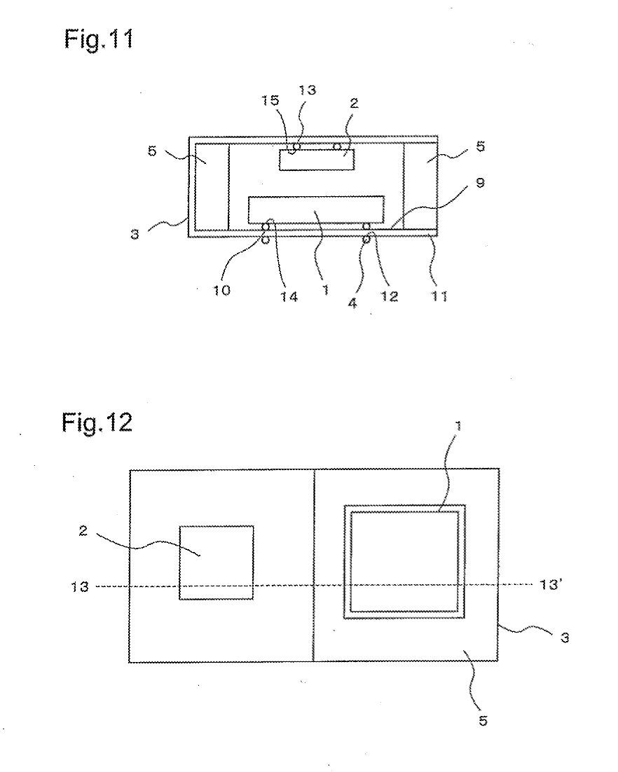

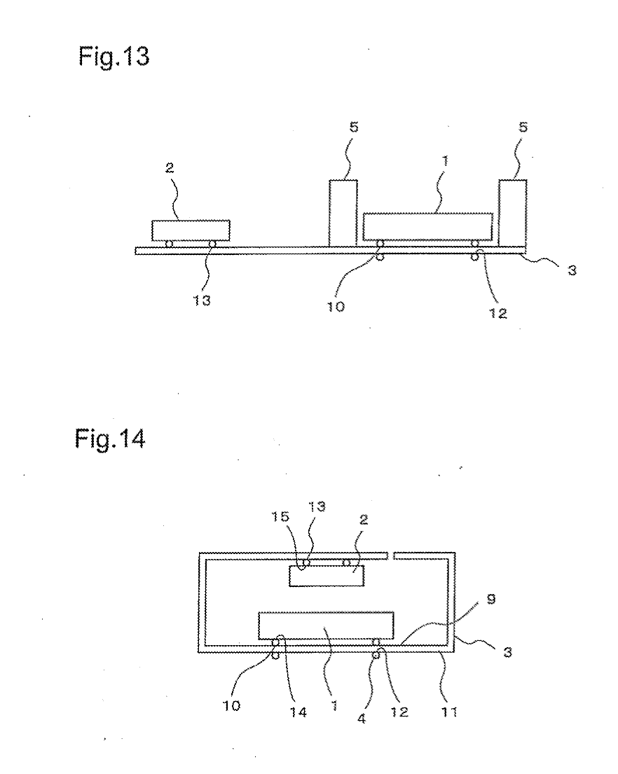

FIG. 11 is a cross-sectional view of a semiconductor device showing a third exemplary embodiment of the present invention. FIG. 12 is a figure (top view) of an assembly in which a device 1 and a device 2 are mounted on the first surface 9 of the flexible circuit substrate 3 used for the semiconductor device of the present invention in a plane arrangement. FIG. 13 is a cross-sectional view showing a cross section along line 13-13′ in FIG. 12.

As shown in FIG. 11, in the semiconductor device of the third exemplary embodiment of the present invention, one flexible circuit substrate 3 having one or more wiring layers is used. One or more first external electrodes 10 and one or more second external electrodes 13 are provided on the first surface 9 of the flexible circuit substrate 3. One or more first external electrodes 12 are provided on the second surface 11 of the flexible circuit substrate 3. The semiconductor device of the third exemplary embodiment of the present invention includes the device 1, the device 2, the support body 5, and the external terminal 4. The device 1 and the device 2 are positioned at a lower side and an upper side, respectively. One or more penetration holes are provided in the support body 5, and the device 1 and the device 2 are accommodated in the penetration hole. The external terminal 4 is electrically connected to the external electrode 12.

In the first exemplary embodiment, the end portions of the flexible circuit substrate 3 are bent along two sides of the support bodies 5 that face each other but in the third exemplary embodiment, the end portion of the flexible circuit substrate 3 is bent along one side of the support bodies 5. This is a difference between the first exemplary embodiment and the third exemplary embodiment. The semiconductor device of the third exemplary embodiment of the present invention has a structure in which one end portion of the flexible circuit substrate 3 is bent along one side of the support bodies 5 so that the device 1, the device 2, and the support body 5 are sandwiched therein. Further, the semiconductor device of the third exemplary embodiment of the present invention has a structure in which there is a gap between the device 1 and the device 2. Thus, there is the gap between the device 1 and the device 2. Therefore, the device 1 is not contact with the device 2 through a member other than the flexible circuit substrate 3 and the support body 5. For this reason, the semiconductor device of the third exemplary embodiment of the present invention has an effect in which since the heat generated by the device 1 is not conducted to the device 2 directly, temperature rise of the device 2 can be suppressed.

In the above-mentioned description, although it is assumed that the temperature of the device 1 is the highest among the devices, even when the temperature of the device 2 is the highest, the heat generated by the device 2 is not conducted to the device 1 directly. For this reason, the semiconductor device of the third exemplary embodiment of the present invention has an effect in which temperature rise of the device 1 can be suppressed.

### Fourth Exemplary Embodiment

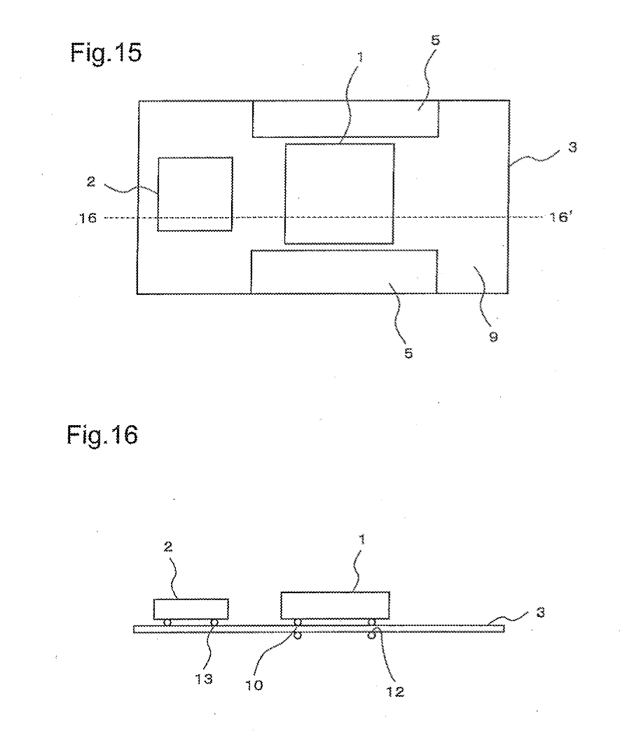

FIG. 14 is a cross-sectional view of a semiconductor device showing a fourth exemplary embodiment of the present invention. FIG. 15 is a figure (top view) of an assembly in which the device 1 and the device 2 are mounted on the first surface 9 of the flexible circuit substrate 3 used for the semiconductor device of the present invention in a plane arrangement. FIG. 16 is a cross-sectional view showing a cross section along line 16-16′ in FIG. 15.

The plurality of support bodies 5 are used in the fourth exemplary embodiment. This is a large difference between the fourth exemplary embodiment and the first to third exemplary embodiments.

As shown in FIG. 14, in the semiconductor device of the fourth exemplary embodiment of the present invention, one flexible circuit substrate 3 having one or more wiring layers is used. One or more first external electrodes 10 and one or more second external electrodes 13 are provided on the first surface 9 of the flexible circuit substrate 3. One or more external electrodes 12 are provided on the second surface 11 of the flexible circuit substrate 3. The semiconductor device of the fourth exemplary embodiment of the present invention includes the device 1, the device 2, the plurality of support bodies 5 (FIG. 15 shows a case in which two support bodies are used), and the external terminal 4. The device 1 is positioned at a lower side and the device 2 is positioned at an upper side. The device 1 and the device 2 are accommodated in an area sandwiched between two support bodies 5. The external terminal 4 is electrically connected to the external electrode 12. The semiconductor device of the fourth exemplary embodiment of the present invention has a structure in which the end portions of the flexible circuit substrate 3 are bent along two sides (this side is the short side among four sides of the support body 5 shown in FIG. 15) of the support bodies 5 that face each other so that the device 1, the device 2, and the support bodies 5 are included therein. Further, the semiconductor device of the fourth exemplary embodiment of the present invention has a structure in which there is the gap between the device 1 and the device 2. Thus, there is the gap between the device 1 and the device 2, and the device 1 is not contact with the device 2 through a member other than the flexible circuit substrate 3 and the support body 5. Therefore, the semiconductor device of the fourth exemplary embodiment of the present invention has an effect in which since the heat generated by the device 1 is not conducted to the device 2 directly, temperature rise of the device 2 can be suppressed.

In the above-mentioned description, it is assumed that the temperature of the device 1 is the highest among the devices. However, even when the temperature of the device 2 is the highest among the devices, the heat generated by the device 2 is not conducted to the device 1 directly. Therefore, the semiconductor device of the fourth exemplary embodiment of the present invention has an effect in which temperature rise of the device 1 can be suppressed.

In the fourth exemplary embodiment of the present invention, because an area occupied by the support body 5 can reduced, many devices and components can be mounted in a space area or a larger size device and component can be mounted. Therefore, the fourth exemplary embodiment of the present invention has an effect in which package density can be increased.

### Fifth Exemplary Embodiment

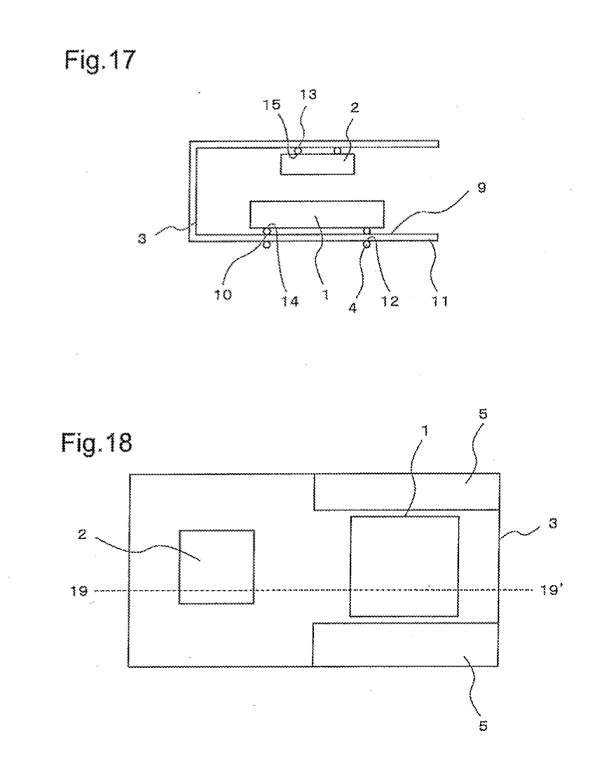

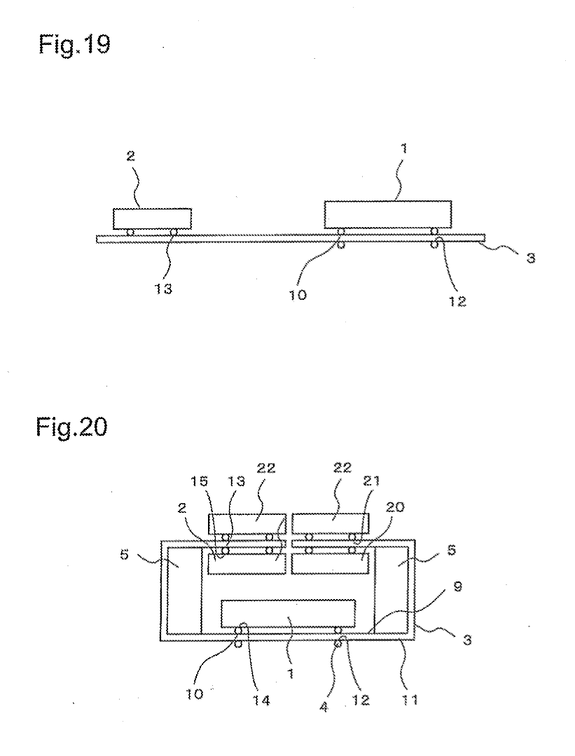

FIG. 17 is a cross-sectional view of a semiconductor device showing a fifth exemplary embodiment of the present invention. FIG. 18 is a figure (top view) of an assembly in which the device 1 and the device 2 are mounted on the first surface 9 of the flexible circuit substrate 3 used for the semiconductor device of the present invention in a plane arrangement. FIG. 19 is a cross-sectional view showing a cross section along line 19-19′ in FIG. 18.

Although the semiconductor device of the fourth exemplary embodiment has a structure in which the end portions of the flexible circuit substrate 3 are bent along two sides of the support bodies 5 that face each other, the semiconductor device of the fifth exemplary embodiment has a structure in which one end portion of the flexible circuit substrate 3 is bent along one side of the support body 5. This is a difference between the fifth exemplary embodiment and the fourth exemplary embodiment.

As shown in FIG. 17, in the semiconductor device of the fifth exemplary embodiment of the present invention, one flexible circuit substrate 3 having one or more wiring layers is used. One or more first external electrodes 10 and one or more second external electrodes 13 are provided on the first surface 9 of the flexible circuit substrate 3. Further, one or more external electrodes 12 are provided on the second surface 11 of the flexible circuit substrate 3. The semiconductor device of the fifth exemplary embodiment of the present invention includes two support bodies. The flexible circuit substrate 3 is bent along the short side of two support bodies 5 and the flexible circuit substrate 3 is bonded to the surface (a rectangular area shown in FIG. 18) of the support body 5. The semiconductor device of the fifth exemplary embodiment of the present invention has a structure in which the device 1 and the device 2 are mounted in an area sandwiched between two support bodies 5. The device 1 is positioned at a lower side and the device 2 is positioned at an upper side. Further, the semiconductor device of the fifth exemplary embodiment of the present invention includes the external terminal 4 that is electrically connected to the external electrode 12.

The semiconductor device of the fifth exemplary embodiment of the present invention has a structure in which one end portion of the flexible circuit substrate 3 is bent along one side of the support body 5 so that the device 1, the device 2, and the support body 5 are sandwiched therein. Further, the semiconductor device of the fifth exemplary embodiment of the present invention has a structure in which there is a gap between the device 1 and the device 2. Thus, there is the gap between the device 1 and the device 2 and the device 1 is not contact with the device 2 through a member other than the flexible circuit substrate 3 and the support body 5. By this, the heat generated by the device 1 is not conducted to the device 2 directly. Therefore, the semiconductor device of the fifth exemplary embodiment of the present invention has an effect in which temperature rise of the device 2 can be suppressed.

In the above-mentioned description, although it is assumed that the temperature of the device 1 is the highest among the devices, even when the temperature of the device 2 is the highest, the heat generated by the device 2 is not conducted to the device 1 directly. Therefore, the semiconductor device of the fifth exemplary embodiment of the present invention has an effect in which temperature rise of the device 1 can be suppressed.

In the fifth exemplary embodiment of the present invention, because an area occupied by the support body 5 can be reduced, many devices and components can be mounted in a space area or a larger size device and component can be mounted. Therefore, the semiconductor device of the fifth exemplary embodiment of the present invention has an effect in which higher device mounting density can be allowed.

As shown in FIG. 17, the semiconductor device of the fifth exemplary embodiment has a structure in which there is a space between two support bodies 5 and the assembly is open at 19′ side of line 19-19′ shown in FIG. 18. Therefore, the semiconductor device of the fifth exemplary embodiment of the present invention has an effect in which the heat radiation performance can be improved in comparison with the semiconductor device according to the first to fourth exemplary embodiments of the present invention because the inside of the semiconductor device can be exposed to the outside air directly.

### Sixth Exemplary Embodiment

FIG. 20 is a cross-sectional view of a semiconductor device showing a sixth exemplary embodiment of the present invention. As shown in FIG. 20, in the semiconductor device of the sixth exemplary embodiment of the present invention, one flexible circuit substrate 3 having one or more wiring layers are used. One or more first external electrodes 10 and one or more second external electrodes 13 are provided on the first surface 9 of the flexible circuit substrate 3. One or more third external electrodes 12 are provided on the second surface 11 of the flexible circuit substrate 3. The semiconductor device of the sixth exemplary embodiment of the present invention includes the device 1, the device 2, the device 20, the support body 5, and the external terminal 4. The device 1 is positioned at a lower side and the devices 2 and 20 are positioned at an upper side. One or more penetration holes are provided in the support body 5 and the device 1, the device 2, and the device 20 are accommodated in the penetration hole. The external terminal 4 is electrically connected to the external electrode 12.

The semiconductor device of the sixth exemplary embodiment of the present invention has a structure in which the end portions of the flexible circuit substrate 3 are bent along two sides of the support bodies 5 that face each other so that the device 1, the device 2, the device 20, and the support body 5 are included therein. Further, the semiconductor device of the sixth exemplary embodiment of the present invention has a structure in which there is a gap between the device 1 and the device 2, between the device 1 and the device 20, and between the device 2 and the device 20. Further, another device 22 is mounted on an upper surface of the semiconductor device. One or more devices 22 can be used. By using such structure, the semiconductor device has an effect in which higher device mounting density can be allowed and the mounting area of the device can be reduced.

As described above, a new type of semiconductor device can be obtained by mounting the another device on the upper surface of the semiconductor device of the first exemplary embodiment. Needless to say, the new type of semiconductor device can also be obtained by mounting the another device on the upper surface of the semiconductor device of the second, third, fourth, or fifth exemplary embodiment like the semiconductor device of the first exemplary embodiment.

### Seventh Exemplary Embodiment

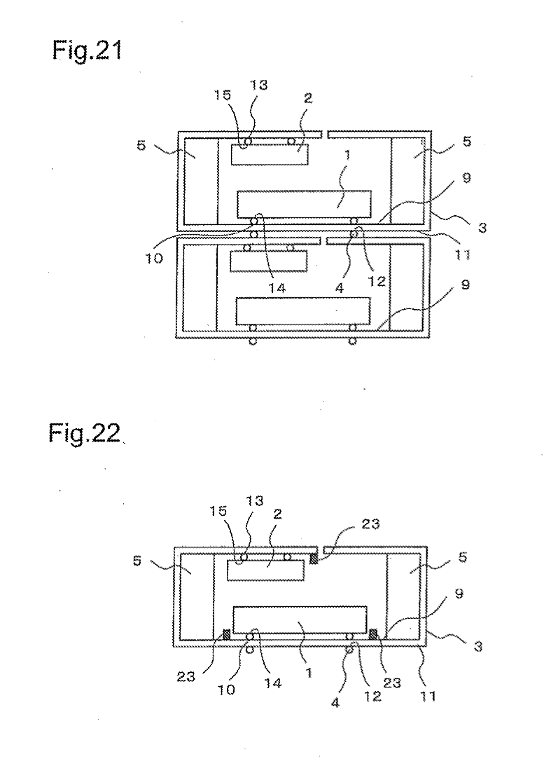

FIG. 21 is a cross-sectional view of a semiconductor device of a seventh exemplary embodiment of the present invention. As shown in FIG. 21, the semiconductor device of the seventh exemplary embodiment has a structure in which two semiconductor devices of the first exemplary embodiment are stacked. As a result, higher device mounting density can be allowed and the mounting area of the device can be reduced.

As described above, a new type of semiconductor device can be obtained by stacking two semiconductor devices of the first exemplary embodiment. Needless to say, the new type of semiconductor device can also be obtained by stacking two semiconductor devices of the second, third, fourth, or fifth exemplary embodiment like the semiconductor device of the first exemplary embodiment.

Further, needless to say, the new type of semiconductor device can also be obtained by choosing two or more semiconductor devices that are different from each other from the semiconductor devices of the second, third, fourth, and fifth exemplary embodiments and stacking them.

### Eighth Exemplary Embodiment

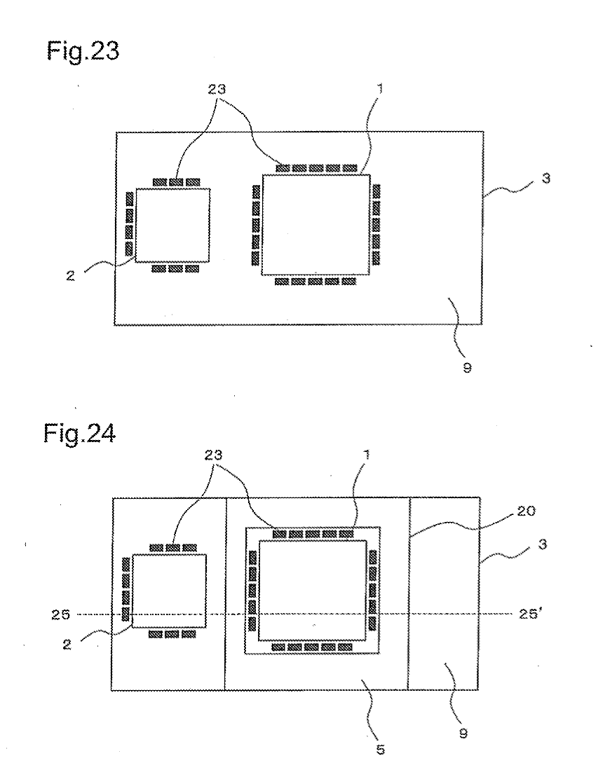

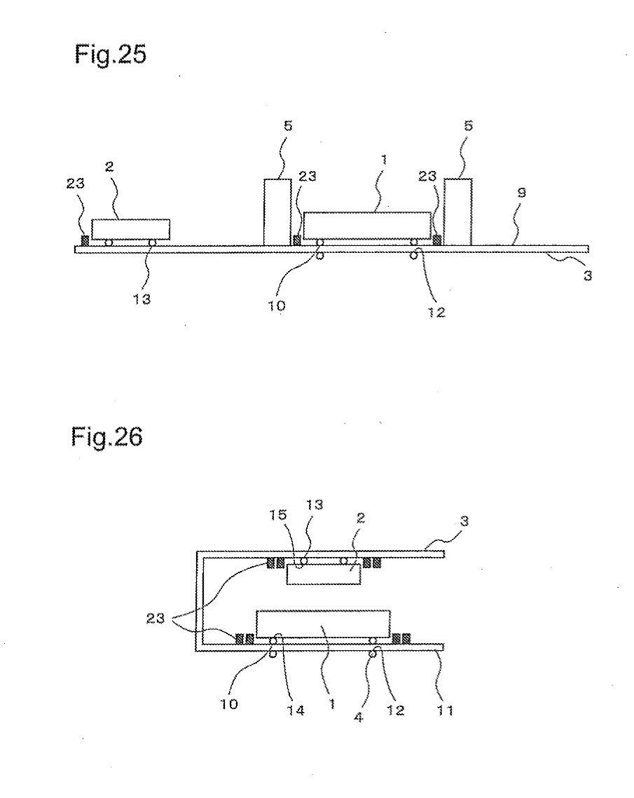

FIG. 22 is a cross-sectional view of a semiconductor device of the eighth exemplary embodiment of the present invention. FIG. 23 is a figure (top view) of an assembly in which the device 1, the device 2, and passive components 23 (capacitor, resistor, inductor, and the like) are mounted on the first surface 9 of the flexible circuit substrate 3 used for the semiconductor device of the present invention in a plane arrangement. FIG. 24 is a figure (top view) of an assembly in which after mounting the device 1, the device 2, and the passive components 23 on the flexible circuit substrate 3, the support body 5 in which a penetration hole is provided so as to surround the device 1 and the passive components 23 is bonded to the first surface 9 of the flexible circuit substrate 3 or is connected to the external electrode 10 formed on the first surface 9. FIG. 25 is a cross-sectional view showing a cross section along line 25-25′ in FIG. 24.

The semiconductor device of the eighth exemplary embodiment of the present invention is similar to the semiconductor device showing the first exemplary embodiment of the present invention shown in FIG. 2, FIG. 3, FIG. 4, and FIG. 5. However, the semiconductor device of the eighth exemplary embodiment of the present invention has a structure in which the passive components are mounted around the device 1 and the device 2. This is difference between the semiconductor device of the eighth exemplary embodiment and the semiconductor device of the first exemplary embodiment. When the device 1 and the device 2 are for example, CPUs (Central Processing Unit) that operate at high speed or high-speed DRAMs, by using the structure of the eighth exemplary embodiment of the present invention, a resistor for impedance matching, a bypass capacitor, and the like are mounted around the device and whereby, malfunction or abnormal operation of the semiconductor device can be—ed. Therefore, the structure of the eighth exemplary embodiment of the present invention is useful.

### Ninth Exemplary Embodiment

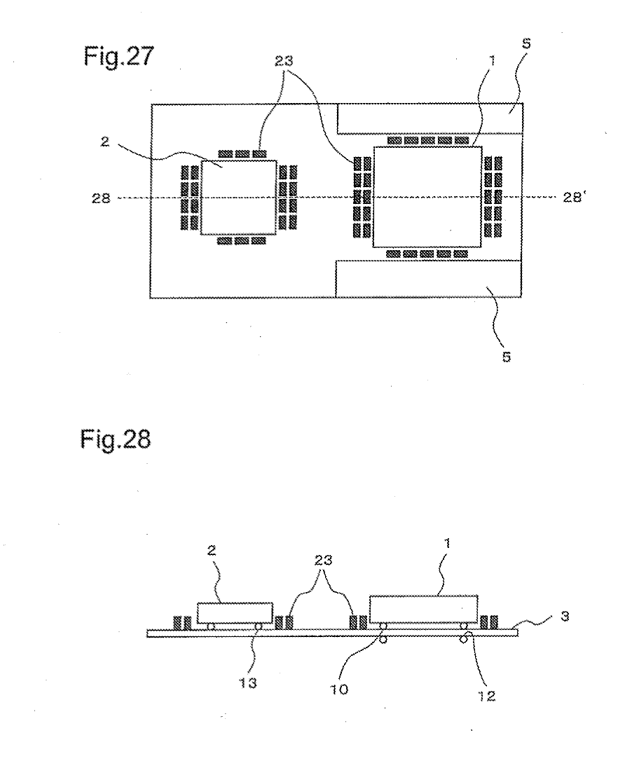

FIG. 26 is a cross-sectional view of a semiconductor device showing a ninth exemplary embodiment of the present invention. FIG. 27 is a figure (top view) of an assembly in which the device 1, the device 2, the passive components 23, and the support body 5 are mounted on the first surface 9 of the flexible circuit substrate 3 used for the semiconductor device of the present invention in a plane arrangement. FIG. 28 is a cross-sectional view showing a cross section along line 28-28′ in FIG. 27.

The ninth exemplary embodiment of the present invention is similar to the eighth exemplary embodiment of the present invention. However, in the ninth exemplary embodiment, two flat plates are used as the support body 5. This is a difference between them. By using the ninth exemplary embodiment of the present invention, the mounting area of the support body 5 can be reduced and whereby, many passive components 23 can be mounted. The ninth exemplary embodiment of the present invention has a merit in which the flexibility of design of the resistor for impedance matching and the bypass capacitor for electrical noise reduction can be increased.

### Tenth Exemplary Embodiment

In an electronic device using the semiconductor device of the present invention described above, the temperature rise of the device can be suppressed compared with a general one (this is not shown in the drawings). Therefore, the semiconductor device of the present invention can be used for a small electronic device in which high operating temperature problem easily occurs. The present invention can be suitably applied to the electronic device such as a home game machine, a medical equipment, a workstation, a server, a personal computer, a car navigation device, a mobile phone, a robot, or the like.

The semiconductor device of the exemplary embodiment has a so-called three-dimensional integration structure in which after the device 1 and the device 2 are mounted on the first face of the flexible circuit substrate, the flexible circuit substrate is bent and whereby, the device 1 and the device 2 are positioned at a lower side and an upper side, respectively. Therefore, the mounting area of the device can be reduced. The support body is mounted on the first surface of the flexible circuit substrate, the device 1 and the device 2 are accommodated in the area in the space surrounded by the support bodies, and the bent flexible circuit substrate is bonded to the support body. Therefore, the three-dimensionally integrated semiconductor device whose shape is stable can be obtained. Additionally, if the structure of the support body is designed so that the thickness of the support body is greater than a total of the mounting height (thickness) of the device 1 and the mounting height (thickness) of the device 2, the gap can be formed between the device 1 and the device 2. Therefore, a structure in which the heat generated by the device 1 is less conducted to the device 2 and vice versa can be realized. As a result, temperature rise of the device can be suppressed. When a general three-dimensional mounting module technology is used, a module composed of a particular combination of the devices cannot be realized because of a heat problem (when the module operates, the temperature of the device exceeds an operation guaranteed temperature of the device). However, when the three-dimensional integration technology of the present invention is used, the module composed of the above-mentioned particular combination of the devices can be realized because the above-mentioned problem does not occur. Therefore, the semiconductor device that can be used for a wide range of system devices can be provided.

The three-dimensionally integrated semiconductor device according to the exemplary embodiment of the present invention has a structure in which by using “one flat plate in which at least one or more penetration holes are provided in a center portion thereof” as the support body in the semiconductor device, the device 1 and the device 2 can be accommodated in the penetration hole provided in the support body. Therefore, the device 1 and the device 2 can be protected from damage due to mechanical impact and force from outside.

Further, in the three-dimensionally integrated semiconductor device according to the exemplary embodiment of the present invention, two flat plates are used as the support body in the semiconductor device and the support bodies are mounted so that the support bodies are positioned approximately parallel to two sides of the device 1 having a rectangular shape that face each other. A structure in which the flexible circuit substrate is bent along at least one side surface of the support body positioned in a vertical direction to two sides of the device 1 that face each other and bonded to the support body can be realized. Therefore, a mounting area and a volume of the support body can be reduced and as a result, a more lightweight three-dimensionally integrated semiconductor device can be realized. Further, because the mounting area of the support body decreases, many devices can be mounted on the first surface of the flexible circuit substrate and a structure in which higher device mounting density can be allowed can be realized.

Further, in the three-dimensionally integrated semiconductor device according to the exemplary embodiment of the present invention, even when an arithmetic processing device such as a CPU (Central Processing Unit) that usually consumes a large amount of power or the like is used as the device 1 and a DRAM (Dynamic Random Access Memory) or a flash memory is used as the device 2, the heat generated by the arithmetic processing device is less conducted to the memory. Therefore, a high-performance and small semiconductor device in which a problem of malfunction and failure of the memory does not occur can be realized.

Further, in the three-dimensionally integrated semiconductor device according to the exemplary embodiment of the present invention, if the external terminal is positioned at the lowermost position, the device 1 (arithmetic processing device) is positioned at an upper side. Therefore, if a heatsink is provided above the device 1 and on the flexible circuit substrate, the cooling effect can be further improved.

Further, the three-dimensionally integrated semiconductor device according to the exemplary embodiment of the present invention has a structure in which even when a device which operates at high speed is used, at least one or more passive components (a bypass capacitor, a resistor for impedance adjustment, and the like) are mounted around the device 1, around the device 2, or around both the device 1 and the device 2 can be realized. Therefore, the malfunction of the semiconductor device can be prevented and a high-performance and small semiconductor device can be realized.

Further, the three-dimensionally integrated semiconductor device according to the exemplary embodiment of the present invention has a structure in Which a plurality of the devices 1 or a plurality of the devices 2 are included or a structure in which a plurality of the devices 1 and a plurality of the devices 2 are included. Therefore, even when the semiconductor device includes many devices, a small semiconductor device can be realized.

Further, by using the three-dimensionally integrated semiconductor device according to the exemplary embodiment of the present invention, the semiconductor device whose shape is stable can be obtained by using any one of a metal such as Fe, an alloy including Ni and Fe, aluminum, an alloy including aluminum, copper, an alloy including Ni and Cr, an alloy including Cr, or the like, silicon, a resin material, and mica as a material of the support body used for the semiconductor device. Additionally, the semiconductor device whose price is relatively low can also be obtained.

Further, by using the three-dimensionally integrated semiconductor device according to the exemplary embodiment of the present invention, a lightweight semiconductor device can be obtained because a penetration hole or a slot is formed in the support body used for the semiconductor device in order to reduce the volume of the support body itself. Here, the penetration hole is a hole provided on the flat plate other than the “penetration hole” in the above-mentioned “one flat plate in which at least one or more penetration holes are provided in a center portion thereof”.

Further, the three-dimensionally integrated semiconductor device according to the exemplary embodiment of the present invention has a structure in which a metal or silicon is used as a material of the support body and the support body is electrically connected to the ground of the flexible circuit substrate. Therefore, a low noise and high-performance semiconductor device can be realized.

Further, in the three-dimensionally integrated semiconductor device according to the exemplary embodiment of the present invention, either a semiconductor bare chip or a packaged semiconductor device is used for the device. Therefore, for example, when the semiconductor bare chip is used as the device, a small and thin three-dimensionally integrated semiconductor device can be realized. On the other hand, when the packaged semiconductor device is used as the device, the outer size and the mounting height thereof increase. However, instead, an inspection cost (cost of an inspection apparatus, cost of a jig and tool, cost for inspection work, and the like) of the device can be largely reduced and whereby, a low-cost semiconductor device can be realized.

Further, the three-dimensionally integrated semiconductor device according to the exemplary embodiment of the present invention has a structure in which another device is stacked on the semiconductor device and the semiconductor device is electrically connected to the device. Therefore, even when the above-mentioned device is mounted as a new component, a small semiconductor device can be realized without increasing the mounting area.

Further, by using the three-dimensionally integrated semiconductor device according to the exemplary embodiment of the present invention, a structure in which two or more same type of three-dimensionally integrated semiconductor devices or two or more different type of three-dimensionally integrated semiconductor devices described above are stacked and these three-dimensionally integrated semiconductor devices are electrically connected to each other can be realized. Therefore, although the semiconductor device uses many devices, the semiconductor device having small mounting area can be realized.

Further, by using the electronic device according to the exemplary embodiment of the present invention, the above-mentioned three-dimensionally integrated semiconductor device is mounted. Therefore, a component can be selected from a wide range of devices and a high-performance and small electronic device can be provided.

A plurality of exemplary embodiments has been described above. Needless to say, the present is not limited to the above-mentioned exemplary embodiments when the modification is made without departing from the gist of the present invention.

### Example 1

Next, an example of manufacturing the three-dimensionally integrated semiconductor device of the present invention will be described.

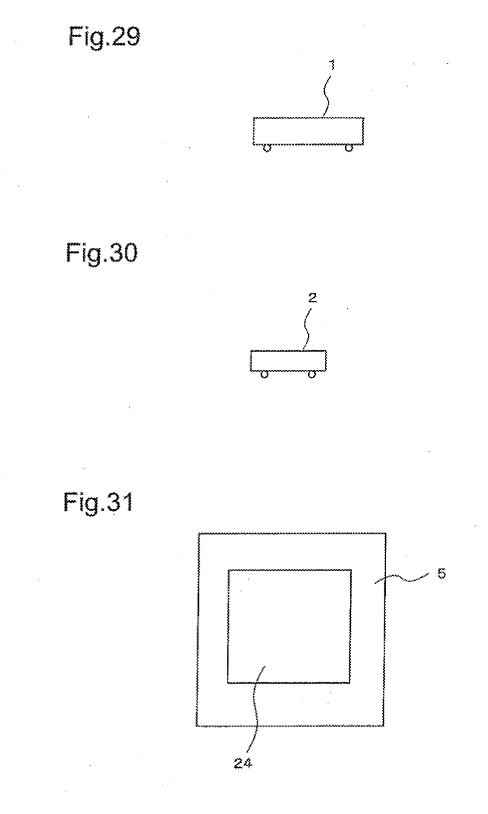

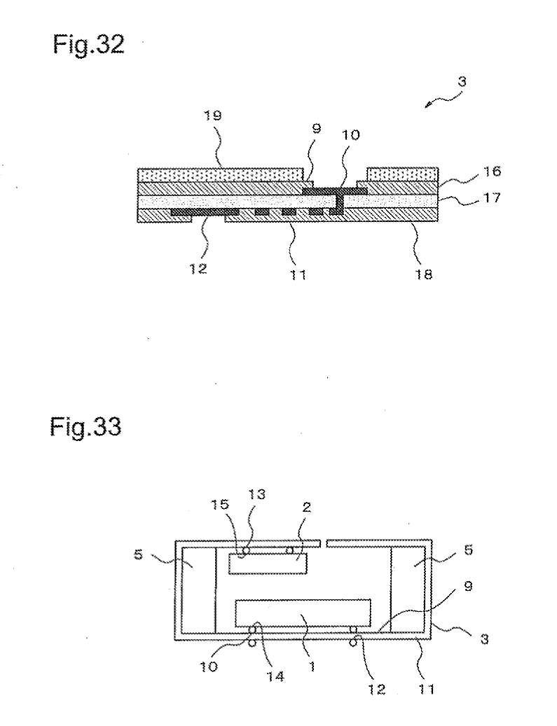

In order to produce the semiconductor device of the present invention, one semiconductor device 1 (outer size: approx. 22 mm×22 mm×1.7 mm height) as shown in FIG. 29 and one semiconductor device 2 (outer size: approx. 11 mm×13 mm×1.2 mm height) shown in FIG. 30 are prepared. The support body 5 (outer size: approx. 33 mm×35 mm×4 mm thickness) as shown in FIG. 31 in which the penetration hole is provided in the center thereof is also prepared. Further, one flexible circuit substrate 3 (outer size: approx. 80 mm×35 mm×0.14 mm thickness) as shown in FIG. 32 is prepared. The flexible circuit substrate 3 is composed of for example, a first insulating layer 16, a second insulating layer 17, and a third insulating layer 18 and has two wiring layers. About four hundred and twenty nine SnAgCu solder balls having a diameter of approx. 0.6 mm that are used as the external terminal of the semiconductor device of the present invention are prepared. In this example, it has been explained that the flexible circuit substrate 3 has two layers. However, needless to say, the semiconductor device of the present invention can be realized by using the flexible circuit substrate 3 that has one layer, or three or more layers.

As shown in FIG. 32, a thermoplastic adhesive film 19 of approximately 25 μm in thickness is bonded to the first surface 9 of the flexible circuit substrate 3 as an adhesive layer in advance that is a portion to which the surface of the support body 5 is bonded. A material that can be bonded at temperature not lower than 150 degrees C. is used for the thermoplastic adhesive film 19.

First, a flux or a cream solder is applied on the external electrode 10 and the external electrode 13 of the first surface 9 of the flexible circuit substrate 3 and the device 1 and the device 2 are temporarily mounted on the flexible circuit substrate 3 by using a mounter. After that, the device 1 and the device 2 are connected to the external terminal 10 and the external terminal 13 of the flexible circuit substrate 3 by soldering by using a reflow equipment. Next, the support body 5 is connected to the external electrode (external electrode connected to the ground) of the flexible circuit substrate 3 by using the conductive adhesive agent. Further, the support body 5 is bonded to a part of the first surface 9 of the flexible circuit substrate 3 by using the conductive adhesive agent. The support body 5 and the flexible circuit substrate 3 are connected and bonded with each other by using the mounter. In the above explanation, an example in which the support body 5 is connected to the ground of the flexible circuit substrate 3 by using the conductive adhesive agent is shown. However, the connection between the support body 5 and the flexible circuit substrate 3 is not necessarily needed. Only the adhesion between the flexible circuit substrate 3 and the support body 5 is enough. When the support body 5 is made of a conductive material such as a metal material, silicon, or the like or a semiconductive material, it is desirable to connect the support body 5 with the ground of the flexible circuit substrate 3 in order to reduce electrical noise of the semiconductor device. However, when the support body 5 is made of an insulating material, it is not necessary to connect the support body 5 with the ground of the flexible circuit substrate 3.

FIG. 5 is a cross-sectional view of the assembly to which the above-mentioned processes have been applied. FIG. 4 is a top view of the assembly to which the above-mentioned processes have been applied.

Next, the semiconductor device is sucked and fixed on a heater stage which is heated to temperature of 180 degrees C. Further, the flexible circuit substrate 3 is bent along two sides 20 of the support body 5 that face each other by using a pressing tool and the flexible circuit substrate 3 is bonded to the surface of the support body 5. The device 1 and the device 2 are enclosed by the support body 5 and the flexible circuit substrate 3 is bonded to the surface of the support body 5. By the above-mentioned method, the three-dimensionally integrated semiconductor device shown in FIG. 33 is produced.

The solder ball that functions as the external electrode 4 of the semiconductor device is temporarily mounted on the external electrode 12 of the package produced by the above-mentioned method with a flux. After that, the solder connection is performed in a reflow oven and the three-dimensionally integrated semiconductor device shown in FIG. 2 is produced.

Next, the produced semiconductor device is temporarily mounted on the mounting board 24 by using the mounter. These semiconductor devices are connected to the mounting board 24 by soldering by using the reflow equipment. Thus, the semiconductor device shown in FIG. 6 is produced.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

Further, it is the inventor's intention to retain all equivalents of the claimed invention even if the claims are amended during prosecution.

The whole or part of the exemplary embodiments disclosed above can be described as, but not limited to, the following supplementary notes.

(Supplementary Note 1)

A three-dimensionally integrated semiconductor device comprising:

a flexible circuit substrate which has a lower portion, an upper portion, and at least one side portion,

a support body which supports the upper portion of the flexible circuit substrate, and

at least two devices mounted on the flexible circuit substrate and wherein

at least one of the devices is mounted on an upper surface of the lower portion of the flexible circuit substrate,

at least one of the other devices is mounted on a lower surface of the upper portion of the flexible circuit substrate, and

a gap is provided between the device mounted on the upper surface of the lower portion of the flexible circuit substrate and the device mounted on the lower surface of the upper portion of the flexible circuit substrate.

(Supplementary Note 2)

The three-dimensionally integrated semiconductor device according to supplementary note 1, wherein

temperature in operating state of the device mounted on the upper surface of the lower portion of the flexible circuit substrate is different from that of the device mounted on the lower surface of the upper portion of the flexible circuit substrate.

(Supplementary Note 3)

The three-dimensionally integrated semiconductor device according to supplementary note 1, wherein

the flexible circuit substrate has the lower portion, the upper portion, and at least two side portions.

(Supplementary Note 4)

The three-dimensionally integrated semiconductor device according to supplementary note 1, wherein

the support body has a shape of a pillar with a hollow portion and at least two devices are arranged in the hollow portion.

(Supplementary Note 5)

The three-dimensionally integrated semiconductor device according to supplementary note 1, wherein

the support body is composed of two or more parts that are separately disposed and at least two devices are arranged in an area surrounded by the two or more parts.

(Supplementary Note 6)

The three-dimensionally integrated semiconductor device according to supplementary note 1, wherein

the three-dimensionally integrated semiconductor device has an opening that is not covered by the flexible circuit substrate and not covered by the support body.

(Supplementary Note 7)

The three-dimensionally integrated semiconductor device according to supplementary note 1, wherein

two or more devices are mounted on one or both of the lower portion and the upper portion of the flexible circuit substrate.

(Supplementary Note 8)

The three-dimensionally integrated semiconductor device according to supplementary note 1, wherein

one or more passive components are mounted around one or more devices.

(Supplementary Note 9)

The three-dimensionally integrated semiconductor device according to supplementary note 1, wherein

at least one device is mounted on the upper surface of the upper portion of the flexible circuit substrate.

(Supplementary Note 10)

A three-dimensionally integrated semiconductor device, wherein

the three-dimensionally integrated semiconductor devices according to supplementary note 1 are stacked therein.

(Supplementary Note 11)

The three-dimensionally integrated semiconductor device according to claim 1, wherein

the support body is made of any one of materials: a metal such as Fe, an alloy including Ni and Fe, aluminum, an alloy including aluminum, copper, an alloy including Ni and Cr, an alloy including Cr, or the like, silicon, a resin material, and mica.

(Supplementary Note 12)

The three-dimensionally integrated semiconductor device according to claim 1, wherein

the support body is made of metal or silicon, and the support body is electrically connected to the ground of the flexible circuit substrate.

(Supplementary Note 13)

The three-dimensionally integrated semiconductor device according to claim 1, wherein

either a semiconductor bare chip or a packaged semiconductor device is used for at least one device.

(Supplementary Note 14)

An electronic device, wherein

the three-dimensionally integrated semiconductor device according to supplementary note 1 is mounted.

In the structure of the three-dimensionally integrated semiconductor device described in patent document 1, a shape of the semiconductor device has to be kept constant. Namely, the Bent Flexible Circuit Substrate has to be Prevented from returning to an original shape by a repulsive force. Accordingly, in the three-dimensionally integrated semiconductor device described in patent document 1, a structure in which semiconductor devices 101 are bonded to each other by the adhesive agent 103 is used. For this reason, for example, in the three-dimensionally integrated semiconductor device in which a semiconductor device such as a high-speed processor that consumes a large amount of power and a memory are used together, heat generated by the high-speed processor is efficiently conducted to the memory via the adhesive agent. As a result, the temperature of the memory rises and exceeds the operation guarantee temperature and whereby, a problem in which malfunction or failure of the memory occurs is generated. As a result, in the three-dimensionally integrated semiconductor device described in patent document 1, the high-speed processor that consumes a large amount of power cannot be used as the semiconductor device.

In the present invention, because there is a gap between at least one device mounted on the upper surface of the lower portion of the flexible circuit substrate and at least one device mounted on the lower surface of the upper portion of the flexible circuit substrate, even when a device (device that generates a large amount of heat) that consumes a large amount of power is used as a semiconductor device, the heat generated by the device is less conducted to another semiconductor device and whereby, malfunction of the semiconductor device does not occur.

What is claimed is:

1. A three-dimensionally integrated semiconductor device comprising:
a flexible circuit substrate which has a lower portion, an upper portion, and at least one side portion,
a support body which supports the upper portion of the flexible circuit substrate, and
at least two devices mounted on the flexible circuit substrate and wherein
at least one of the devices is mounted on an upper surface of the lower portion of the flexible circuit substrate,
at least one of the other devices is mounted on a lower surface of the upper portion of the flexible circuit substrate, and
a gap is provided between the device mounted on the upper surface of the lower portion of the flexible circuit substrate and the device mounted on the lower surface of the upper portion of the flexible circuit substrate.

2. The three-dimensionally integrated semiconductor device according to claim 1, wherein
temperature in an operation state of the device mounted on the upper surface of the lower portion of the flexible circuit substrate is different from that of the device mounted on the lower surface of the upper portion of the flexible circuit substrate.

3. The three-dimensionally integrated semiconductor device according to claim 1, wherein
the flexible circuit substrate has the lower portion, the upper portion, and the at least two side portions.

4. The three-dimensionally integrated semiconductor device according to claim 1, wherein
the support body has a shape of a pillar with a hollow portion and at least two devices are arranged in the hollow portion.

5. The three-dimensionally integrated semiconductor device according to in claim 1, wherein
the support body is composed of two or more parts that are separately disposed and at least two devices are arranged in an area surrounded by two or more parts.

6. The three-dimensionally integrated semiconductor device according to claim 1, wherein
the three-dimensionally integrated semiconductor device has an opening that is not covered by the flexible circuit substrate and not covered by the support body.

7. The three-dimensionally integrated semiconductor device according to claim 1, wherein
two or more devices are mounted on one or both of the lower portion and the upper portion of the flexible circuit substrate.

8. The three-dimensionally integrated semiconductor device according to claim 1, wherein
at least one device is mounted on the upper surface of the upper portion of the flexible circuit substrate.

9. A three-dimensionally integrated semiconductor device, wherein
the three-dimensionally integrated semiconductor devices according to claim 1 are stacked therein.

10. An electronic device, wherein
the three-dimensionally integrated semiconductor device according to claim 1 is mounted.
